(19) United States
(12) Patent Application Publication
(10) Pub. No.: US 2025/0109332 A1
(43) Pub. Date: Apr. 3, 2025

(54) COMPOSITION, ITS USE AND A PROCESS FOR SELECTIVELY ETCHING SILICON-GERMANIUM MATERIAL

(71) Applicant: BASF SE, Ludwigshafen Am Rhein (DE)

(72) Inventors: Francisco Javier LOPEZ VILLANUEVA, Ludwigshafen am Rhein (DE); Chih Hui LO, Taoyuan City (TW); Andreas KLIPP, Ludwigshafen am Rhein (DE); Mei Chin SHEN, Taoyuan City (TW); Sven HILDEBRANDT, Muelheim an der Ruhr (DE)

(21) Appl. No.: 18/730,148

(22) PCT Filed: Feb. 13, 2023
(86) PCT No.: PCT/EP23/53472

§ 371 Date: Jul. 18, 2024

(30) Foreign Application Priority Data
Feb. 23, 2022 (EP) 22158244.8

(51) Int. Cl. C09K 13/00; H01L 21/306

(52) U.S. Cl. CPC C09K 13/00; H01L 21/30604

(57) ABSTRACT

Disclosed herein is a composition for selectively etching a silicon germanium (SiGe) layer in the presence of a silicon layer, the composition including:
(a) 1 to 10% by weight of an oxidizing agent;
(b) 1 to 14% by weight of an etchant comprising a source of fluoride ions;
(c) 0.001 to 3% by weight of a selectivity enhancer of formula S1

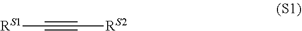

(d) 0.001 to 3% by weight of an additional selectivity enhancer of formula S31

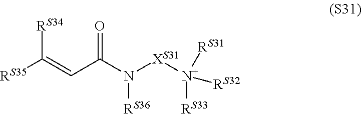

and
(e) water.

The present invention relates to a composition, its use and a process for selectively etching silicon-germanium material at a surface of a microelectronic device substrate, relative to etching a material comprising silicon at the same surface.

### BACKGROUND OF THE INVENTION

Steps of preparing certain microelectronic devices, e.g., integrated circuits, may include selectively removing silicon-germanium (SiGe) material from a surface that contains the SiGe in combination with silicon (Si). According to certain example fabrication steps, SiGe may be used as a sacrificial layer in a structure that also contains silicon. Based on such fabrication steps, advanced device structures may be prepared, such as silicon nanowires and silicon on nothing (SON) structures. Steps in these processes include epitaxial deposition of a structure of alternating layers of Si and SiGe, followed by patterning and, eventually, selective lateral etching to remove the SiGe layers and generate a three-dimensional silicon structure.

In certain specific methods of preparing a field effect transistors (FET) for an integrated circuit, Si and SiGe materials are deposited as layers onto a substrate, i.e., as an “epitaxial stack” of Si and SiGe. The layers are subsequently patterned using standard techniques, such as by use of a standard lithographically generated mask. Next, a directional isotropic etch may be useful to laterally etch away the sacrificial SiGe material, leaving behind a silicon nanowire or sheet structure.

To enable smaller structures within Semiconductor structures electronic industry is searching for solutions to remove SiGe layers selectively against amorphous or crystalline silicon. This is needed to realize well defined nanowire or nanosheet structures.

EP 3 447 791 A1 discloses an etching solution for the selective removal of silicon-germanium over poly silicon from a microelectronic device comprising water, an oxidizer, a water-miscible organic solvent, a fluoride ion source, and optionally a surfactant. Example 5 discloses a composition comprising H₂O₂, NH₄F, butyl diclycol, citric acid, and Surfynol® 485, that is a polyethoxylated dialkyl acetylene compound having an ethylene oxide content (mole) of 30 and aids in the suppression of poly Si etch rate.

Nonpublished International patent application No. PCT/EP2021/072975 discloses a composition for selectively etching a layer comprising a silicon germanium alloy (SiGe) in the presence of a a layer comprising silicon, the composition comprising 5 to 15% by weight of an oxidizing agent, 5 to 20% by weight of an etchant comprising a source of fluoride ions, 0.001 to 3% by weight of a acetylenic hydroxy compound as selectivity enhancer, and water.

However, the state-of-the-art solutions are not able to fulfil all requirements since they have a too high SiOₓ, SiON or SiN etch rate.

It is therefore an object of the invention to keep the SiGe/Si selectivity and to increase the SiGe/SiOₓ, the SiGe/SiON or the SiGe/SiN selectivity, particularly the SiGe/SiOₓ selectivity.

### SUMMARY OF THE INVENTION

It has now been found that the use of low amounts of an ammonium acrylamide compound and its derivatives significantly and selectively improve the SiGe/Si selectivity against SiOₓ, SiON or SiN.

Therefore, one embodiment of the present invention is a composition for selectively etching a silicon germanium alloy (SiGe) layer in the presence of a silicon layer, the composition comprising:
(a) 1 to 10% by weight of an oxidizing agent;
(b) 1 to 14% by weight of an etchant comprising a source of fluoride ions;
(c) 0.001 to 3% by weight of a selectivity enhancer of formula S1

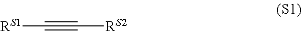

(d) 0.001 to 3% by weight of an additional selectivity enhancer of formula S31

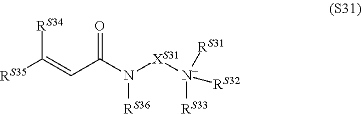

and
(e) water;
wherein
R^{S1} is selected from X^{S}—OH and Y^{S}—(CO)—OH;
R^{S2} is selected from (i) R^{S1}, (ii) H, (iii) C₁ to C₁₀ alkyl, (iv) C₁ to C₁₀ alkenyl, (v) C₁ to C₁₀ alkynyl, and (vi) —X^{S1}—(O—C₂H₃R^{S6})ₘ—OR^{S6}—;
R^{S6} is selected from H and C₁ to C₆ alkyl;
R^{S31}, R^{S32}, R^{S33} are independently selected from C₁ to C₆ alkyl;
R^{S34}, R^{S35}, R^{S36} are independently selected from H and C₁ to C₆ alkyl;
X^{S} is selected from a linear or branched C₁ to C₁₀ alkanediyl, a linear or branched C₂ to C₁₀ alkenediyl, a linear or branched C₂ to C₁₀ alkynediyl, and —X^{S1}—(O—C₂H₃R^{S6})ₘ—;
Y^{S} is selected from a chemical bond and X^{S};
X^{S1} is a C₁ to C₆ alkanediyl;
X^{S31} is selected from a C₁ to C₆ alkanediyl and —X^{S1}—(O—C₂H₃R^{S6})ₘ—;
m is an integer of from 1 to 10.

It was particularly surprising that the etching composition according to the invention is suited to allow for a very controlled and selective etching of layers comprising or consisting of SiGe alloys, preferably of a SiGe25 layer, even of thin or ultra-thin layers comprising germanium (“Ge layers”), particularly layers comprising or consisting of SiGe alloys, while at the same time not or not significantly compromising layers comprising or consisting of silicon (Si), particularly amorphous or crystalline silicon, most particularly crystalline silicon.

Another embodiment of the present invention is the use of the compositions described herein for selectively etching a SiGe layer in the presence of a silicon layer and optionally a silicon oxide layer.

Yet another embodiment of the present invention is a process for selectively removing a silicon-germanium layer from a surface of a microelectronic device relative to a silicon layer, and a layer comprising or consisting of silicon oxide, the process comprising:
(a) providing a microelectronic device surface that includes a silicon layer and silicon-germanium layer,
(b) providing a composition as described herein, and
(c) contacting the surface with the composition for a time and at a temperature effective to selectively remove the silicon-germanium layer relative to the silicon layer and the optional silicon oxide layer.

Yet another embodiment of the present invention is a process for the manufacture of a semiconductor device, comprising the step of selectively removing silicon-germanium from a surface of a microelectronic device relative to a Si material and a silicon oxide material.

### BRIEF DESCRIPTION OF THE FIGURES

FIG. 1 shows the resulting substrate after having performed Example 1;

FIG. 2 shows the resulting substrate after having performed Example 2;

FIG. 3 shows a scheme of the untreated substrate from Example 1 and 2.

### DETAILED DESCRIPTION OF THE INVENTION

The etching composition according to the present invention is particularly useful for etching of silicon-germanium (SiGe) layers in the presence of silicon (Si) layers, and particularly useful if an additional silicon oxide layer is present.

The etching composition comprises (a) 1 to 10% by weight of an oxidizing agent; (b) 1 to 14% by weight of an etchant comprising a source of fluoride ions; (c) 0.001 to 3% by weight of a first selectivity enhancer of formula S1

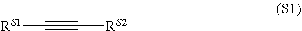

(d) 0.001 to 3% by weight of an additional selectivity enhancer of formula S31

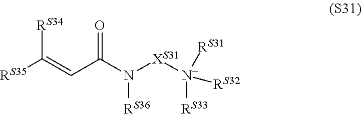

and (d) water, as further described below.

### Definitions

As used herein, a “silicon layer” or “Si layer” is a layer that essentially consists of elemental silicon, preferably consists of elemental silicon. It particularly includes, but is not limited to, a layer consisting of amorphous, poly-crystalline or (single-)crystalline silicon; p-doped silicon; or n-doped silicon. The etching composition is particularly useful when etching silicon, in particular amorphous silicon (aSi) in the presence of SiGe. The term “essentially consisting of silicon” means that the silicon content in the layer is more than 90% by weight, preferably more than 95% by weight, even more preferably more than 98% by weight. When undoped silicon is used, it is particularly preferred that the silicon layer dos not comprises any other elements than silicon. When n- or p-doped silicon is used, it is particularly preferred that the silicon layer is free of any other elements besides the n- or p-dopants, which may be present in an amount below 10% by weight, preferably below 2% by weight. Preferably, the germanium content of the silicon layer is less than 5% by weight, preferably less than 2% by weight, more preferably less than 1% by weight, even more preferably less than 0.1% by weight. Most preferably the silicon layer comprises no germanium.

As used herein, “silicon oxide layers” or “SiOₓ layers” correspond to layers that were deposited from a silicon oxide precursor source, e.g., TEOS, thermally deposited silicon oxide, or carbon doped oxides (CDO) deposited using commercially available precursors such as SiLK™, AURORA™, CORAL™ or BLACK DIAMOND™. “Silicon oxide” is meant to broadly include SiO&, CDO's, siloxanes and thermal oxides. Silicon oxide or SiOₓ material corresponds to pure silicon oxide (SiO₂) as well as impure silicon oxide including impurities in the structure.

As used herein, the “silicon-germanium layers” or “SiGe layers” correspond to layers essentially consisting of silicon-germanium (SiGe) alloys known in the art. The term “essentially consisting of silicon germanium” means that the SiGe content in the layer is more than 90% by weight, preferably more than 95% by weight, even more preferably more than 98% by weight, and most preferably consists of SiGe. When n- or p-doped silicon germanium is used, it is particularly preferred that the silicon germanium layer is free of any other elements besides the n- or p-dopants, which may be present in an amount below 10% by weight, preferably below 2% by weight. Silicon germanium or SiGe is generally represented by the formula SiₓGe_{y}, wherein x is in a range from about 0.50 to about 0.90, particularly about 0.60 to about 0.85 or about 0.70 to about 0.90, and y is in a range from about 0.10 to about 0.50, particularly from about 0.15 to about 0.40 or about 0.10 to about 0.30, with x+y=1.00. SiGe25 here means that y is 0.25, which is particularly preferred.

As used herein, the formula SiGe will be used to signify the silicon germanium material to be removed.

As used herein, the term “selectively etching” (or “selective etch rate”) preferably means that upon applying a composition according to the invention to a layer comprising or consisting of a first material, in this case SiGe, in the presence of a layer comprising or consisting of a second material, in this case a silicon material, most particularly aSi, the etch rate of said composition for etching the first layer is more than 500 times, preferably more than 750 times, most preferably more than 1000 times, the etch rate of said composition for the second layer. Depending on the substrate to be etched, other layers comprising or consisting of silicon like SiOₓ, SiON or SiN should also not be jeopardized.

As used herein, the term “layer” means a part of a substrate that was separately disposed on the surface of a substrate and has a distinguishable composition with respect to adjacent layers.

As used herein, “chemical bond” means that the respective moiety is not present but that the adjacent moieties are bridged so as to form a direct chemical bond between these adjacent moieties. By way of example, if in a molecule A-B-C the moiety B is a chemical bond then the adjacent moieties A and C together form a group A-C.

The term “Cₓ” means that the respective group comprises x numbers of C atoms. The term “Cₓ to C_{y} alkyl” means alkyl with a number x to y of carbon atoms and, unless explicitly specified, includes unsubstituted linear, branched and cyclic alkyl. As used herein, “alkyl” refers to linear, branched or cyclic alkyl or a combination thereof. As used herein, “alkanediyl” refers to a diradical of linear, branched or cyclic alkanes or a combination thereof.

All percent, ppm or comparable values refer to the weight with respect to the total weight of the respective composition except where otherwise indicated. The term wt % means % by weight.

All cited documents are incorporated herein by reference.

### Oxidizing Agent

The etching composition according to the invention comprises an oxidizing agent. The oxidizing agent, also referred to as “oxidizer”, may be one or more compounds that are capable of oxidizing Germanium within Silicon Germanium alloys.

Preferably the oxidizing agent is different from the other components of the composition, particularly different from the etching agent. Therefore, the oxidizing agent is preferably free of any source of fluoride ions.

Oxidizing agents contemplated herein include, but are not limited to, hydrogen peroxide, FeCl₃, FeF₃, Fe(NO₃)₃, Sr(NO₃)₂, CoF₃, MnF₃, oxone (2KHSO₅ KHSO₄ K₂SO₄), periodic acid, iodic acid, vanadium (V) oxide, vanadium (IV,V) oxide, ammonium vanadate, ammonium peroxy-monosulfate, ammonium chlorite, ammonium chlorate, ammonium iodate, ammonium nitrate, ammonium perborate, ammonium perchlorate, ammonium periodate, ammonium persulfate, ammonium hypochlorite, ammonium hypobromite, ammonium tungstate, sodium persulfate, sodium hypochlorite, sodium perborate, sodium hypobromite, potassium iodate, potassium permanganate, potassium persulfate, nitric acid, potassium persulfate, potassium hypochlorite, tetramethylammonium chlorite, tetramethylammonium chlorate, tetramethylammonium iodate, tetramethylammonium perborate, tetramethylammonium perchlorate, tetramethylammonium periodate, tetramethylammonium persulfate, tetrabutylammonium peroxymonosulfate, peroxy-monosulfuric acid, ferric nitrate, urea hydrogen peroxide, peracetic acid, methyl-1,4-benzo-quinone (MBQ), 1,4-benzoquinone (BQ), 1,2-benzoquinone, 2,6-dichloro-1,4-benzoquinone (DCBQ), toluquinone, 2,6-dimethyl-1, 4-benzoquinone (DMBQ), chloranil, alloxan, N-methyl-morpholine N-oxide, trimethylamine N-oxide, and combinations thereof. The oxidizing species may be introduced to the composition at the manufacturer, prior to introduction of the composition to the device wafer, or alternatively at the device wafer, i.e., in situ.

Preferably the oxidizing agent comprises or consists of a peroxide. Useful peroxides may be but are not limited to hydrogen peroxide or peroxymonosulfuric acid and organic acid peroxides like peroxyacetic acid, and their salts.

The most preferred oxidizing agent is hydrogen peroxide.

The oxidizing agent may be used in an amount of from about 1 to about 10% by weight, preferably from about 2 to 8% by weight, even more preferably from about 3 to about 7% by weight, most preferably of from about 4 to about 6% by weight, based on the total weight of the composition.

### Etchant

The etching composition according to the invention comprises a source of fluoride ions which may be any compound that is capable of releasing fluoride ions.

Preferably, the etchant is different from the other component in the composition, particularly is different from the oxidizing agent. Therefore, the etchant preferably has no oxidizing capabilities with respect to any of the materials on the surface of the substrate to be treated, particularly Si or SiGe.

Preferred etchants are selected from but not limited to the group consisting of ammonium fluoride, ammonium bifluoride, triethanolammonium fluoride, diglycolammonium fluoride, methyldiethanolammonium fluoride, tetramethylammonium fluoride, triethylamine trihydrofluoride, hydrogen fluoride, fluoroboric acid, tetrafluoroboric acid, ammonium tetra-fluoro-borate, fluoroacetic acid, ammonium fluoroacetate, trifluoroacetic acid, fluorosilicic acid, ammonium fluorosilicate, tetrabutylammonium tetrafluoroborate, and mixtures thereof. Preferably the etchant consists of one or more, most preferably one of the said compounds.

Most preferably the etchant comprises or consists of ammonium fluoride, ammonium hydrogen fluoride, and hydrogen fluoride. Most preferably the etchant comprises or consists of ammonium fluoride.

The etching compositions according to the invention comprising ammonium fluoride as the etchant have shown a stable and reproducible controlled selective etch rate for etching a layer comprising or consisting of SiGe, in particular SiGe25, in the presence of a layer comprising or consisting of Si.

The etchant may be used in an amount of from about 1 to about 14% by weight, preferably of from about 2 to about 12% by weight, more preferably of from about 4 to about 10% by weight, even more preferably of from about 4 to about 10% by weight, most preferably of from about 6 to about 8% by weight, based on the total weight of the composition.

Compositions according to the invention comprising the etchant in the here defined preferred total amounts have shown a superior etch rate, in particular for etching a layer comprising or consisting of SiGe, preferably of SiGe25, and etch rate selectivity, in the presence of a layer comprising or consisting of Si.

### SiGe Selectivity Enhancer

The first SiGe selectivity enhancer (also referred to as “selectivity enhancer”) of formula S1

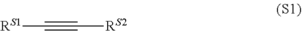

selectively reduces the etch rate of Si layers, whereas the etch rate of SiGe layers, preferably of SiGe25, are still high, which leads to SiGe/Si, particularly SiG2/a-Si selectivities above 500 or even above 1000.

In formula S1 R^{S1} may be selected from X^{S}—OH and Y^{S}—(CO)—OH, wherein X^{S} may be a linear or branched C₁ to C₁₀ alkanediyl, a linear or branched C₂ to C₁₀ alkenediyl, linear or branched C₂ to C₁₀ alkynediyl, or a polyoxyalkylene group —X^{S1}—(O—C₂H₃R⁶)ₘ—; Y^{S1} may be the same as X^{S} or may be a chemical bond. If R^{S1} is a polyoxyalkylene group, X^{S1} may be a C₁ to C₆ alkanediyl, preferably ethanediyl, propanediyl or butanediyl; furthermore, it is important that m is integer selected from 1 to 10, preferably from 1 to 5, even more preferably from 1 to 3, most preferably from 1 to 2. The higher m is the lower is the effect of the selectivity enhancer. If m is too high, the selectivity enhancers do not sufficiently reduce the a-Si, SiOₓ, SiON or SiN etch rates.

R^{S2} may be selected from R^{S1}, preferably R^{S2} is the same as R^{S1} describe above. Alternatively R^{S2} may be (ii) H, (iii) a C₁ to C₁₀ alkyl, (iv) a C₁ to C₁₀ alkenyl, (v) a C₁ to C₁₀ alkynyl, and (vi) —X^{S1}—(O—C₂H₃R^{S6})ₘ—OR^{S6}, wherein X^{S1} is a C₁ to C₆ alkanediyl, preferably ethanediyl, propanediyl or butanediyl; R^{S6} is selected from H and C₁ to C₆ alkyl, preferably H, methyl or ethyl; and m may be an integer of from 1 to 10.

Most preferably R^{S1} and R^{S2} are the same.

In a first preferred embodiment R^{S1} may be X^{S}—OH. Preferably X^{S} may be a C₁ to C₆ alkanediyl, more preferably a C₁ to C₆ alkane-1,1-diyl.

Preferably X^{S} is selected from a C₃ to C₁₀ alkanediyl, more preferably from C₄ to C₈ alkanediyl.

Particularly preferably X^{S} is selected from methanediyl, ethane-1,1-diyl, and ethane-1,2-diyl. In a another preferred embodiment X^{S} is selected from propan-1,1-diyl, butane-1,1-diyl, pentane-1,1-diyl, and hexane-1,1-diyl. In yet another preferred embodiment X^{S} is elected from propane-2-2-diyl, butane-2,2-diyl, pentane-2,2-diyl, and hexane-2,2-diyl. In yet another preferred embodiment X^{S} is elected from propane-1-2-diyl, butane-1,2-diyl, pentane-1,2-diyl, and hexane-1,2-diyl. In yet another preferred embodiment X^{S} is elected from propane-1-3-diyl, butane-1,3-diyl, pentane-1,3-diyl, and hexane-1,3-diyl. Particular preferred groups X^{S} are butane-1,1-diyl, pentane-1,1-diyl, and hexane-1,1-diyl, heptane-1,1-diyl and octane-1,1-diyl.

Preferably the first selectivity enhancer is a compound of formula S2

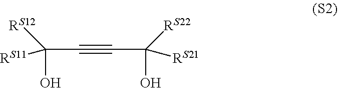

wherein
R^{S11}, R^{S21} are independently selected from a C₁ to C₁₀ alkyl, preferably from ethyl, propyl, butyl, pentyl and hexyl, most preferably from propyl, butyl, or pentyl.
R^{S12}, R^{S22} are independently selected from H and a C₁ to C₄ alkyl, preferably H, methyl or ethyl.

Most preferably the (first) selectivity enhancer may be a compound of formula S4

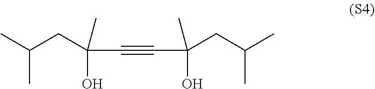 [SMILES: CC(C)CC(C)(O)C#CC(C)(O)CC(C)C]

available from Evonik under the trade name Surfynol® 104.

The selectivity enhancer of the first preferred embodiment may be present in an amount of from about 0.0005 to about 0.03% by weight, preferably of from about 0.001 to about 0.02% by weight, most preferably of from about 0.005 to about 0.015% by weight. A single selectivity enhancer may increase the SiGe/Si selectivity up to more than 500, preferably more than 750, most preferably more than 1000.

In a second preferred embodiment, R^{S1} may be Y^{S}—(CO)—OH, wherein Y^{S1} may be a chemical bond or the same as X^{S} described above.

Preferably the (first) selectivity enhancer may be a compound of formula S3

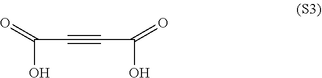

The selectivity enhancer of the second preferred embodiment may be present in an amount of from about 0.1 to about 3% by weight, preferably of from about 0.5 to about 2% by weight.

The composition according to the invention may comprise one or more of the selectivity enhancers described herein.

A particularly preferred composition comprises one single selectivity enhancer of the first preferred embodiment, particularly one single selectivity enhancer of formula S2 or formula S4.

Another particularly preferred composition comprises a first selectivity enhancer of the first preferred embodiment, particularly a first selectivity enhancer of formula S2 or formula S4; and further comprises a second selectivity enhancer of the second preferred embodiment, particularly a second selectivity enhancer of formula S3. If a first selectivity enhancer of formula S2 or formula S4 and a second selectivity enhancer of formula S3 are used the weight ratio of first and the second selectivity enhancer preferably is from 0.0001 to 0.1, most preferably from 0.001 to 0.02. The combination of a first and a second selectivity enhancer may increase the SiGe/Si selectivity up to more than 10⁴.

### Additional SiGe Selectivity Enhancer

It has been found that an additional SiGe selectivity enhancer of formula S31 (also referred to as “additional selectivity enhancer”)

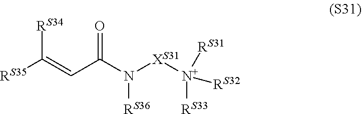

may further increase the SiGe selectivity over the silicon layer, and particularly over silicon oxide.

In formula S31 the ammonium substituents R^{S31}, R^{S32}, R^{S33} may independently be selected from C₁ to C₆ alkyl, preferably methyl, ethyl, propyl, and butyl, most preferably methyl or ethyl. The acrylic substituents R^{S34} and R^{S35} as well as the amide substituent R^{S36} may independently be selected from H and C₁ to C₆ alkyl, preferably H and C₁ to C₄ alkyl, most preferably H. The divalent spacer X^{S31} may be selected from a C₁ to C₆ alkanediyl and a (poly)alkoxy group —X^{S1}—(O—C₂H₃R^{S6})ₘ—, wherein X^{S1} is a C₁ to C₆ alkanediyl, preferably methyl, ethyl, propyl, or butyl, most preferably, R^{S6} is selected from H and C₁ to C₆ alkyl, preferably H and C₁ to C₄ alkyl, most preferably H and methyl, and m is an integer of from 1 to 10, preferably 1 to 6.

In a preferred embodiment of additional selectivity enhancer
R^{S31}, R^{S32}, R^{S33} are independently selected from methyl, ethyl, propyl and butyl;
R^{S34}, R^{S35}, R^{S36} are independently H or selected from methyl, ethyl, propyl and butyl;
X^{S31} is selected from methanediyl, ethanediyl, propanediyl, butanediyl, and —X^{S1}—(O—C₂H₃R^{S6})ₘ—;
R^{S6} is H or selected from methyl and ethyl;
X^{S1} is methanediyl, ethanediyl, propanediyl, butanediyl;
m is an integer of from 1 to 6.

In another preferred embodiment of additional selectivity enhancer
R^{S31}, R^{S32}, R^{S33} are independently selected from methyl and ethyl;
R^{S34}, R^{S35}, R^{S36} are independently H or methyl;
X^{S31} is methanediyl, ethane-1,2-diyl, propane-1,3-diyl, or butane-1,4-diyl;
X^{S1} is methanediyl, ethane-1,2-diyl, propane-1,3-diyl, or butane-1,4-diyl;
m is an integer of from 1 to 6.

In another preferred embodiment the additional selectivity enhancer is a compound of formula S32

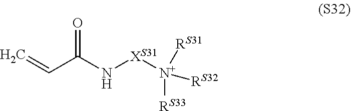

wherein
R^{S31}, R^{S32}, R^{S33} are independently selected from methyl, ethyl, propyl or butyl;
X^{S31} is selected from methanediyl, ethanediyl, propanediyl, and butanediyl.

The additional selectivity enhancer is usually present in the etching composition in an amount of from about 0.005 to about 5% by weight, preferably of from about 0.01 to about 3% by weight, even more preferably from about 0.1 to about 1% by weight, most preferably from about 0.1 to about 0.5% by weight, based on the total weight of the composition.

### Bath Stabilizer

The composition may further comprise a hydroxy carboxylic acid (also referred to herein as “bath stabilizer”). The bath stabilizer significantly increases the lifetime of the SiGe etching composition.

As used herein, “hydroxy carboxylic acid” means a carboxylic acid comprising at least on carboxy group (C═O) and at least one hydroxy group (—OH).

In a preferred embodiment hydroxy carboxylic acid is a dihydroxy carboxylic acid, particularly a dihydroxy dicarboxylic acid.

A particularly preferred hydroxy carboxylic acid is tartaric acid.

The abath stabilizer may be present in the etching composition in an amount of from about 0.01 to about 3% by weight, preferably of from about 0.05 to about 2% by weight, most preferably from about 0.1 to about 1% by weight, based on the total weight of the composition.

### Acid

The etching composition according to the invention may further comprise an acid. Such acid may be an inorganic acid, an organic acid, or a combination thereof. Preferably the acid is an organic acid or a combination of an inorganic acid and an organic acid.

Typical inorganic acids may be selected from but are not limited to sulfuric acid or phosphoric acid. Preferably, the inorganic acid comprises or consists of a strong inorganic acid, particularly sulfuric acid.

Typical organic acids may be selected from but are not limited to C₁ to C₁₀ mono, di or tri carboxylic acids, sulfonic acids, phosphonic acids, and the like. Preferred are C₁ to C₁₀ mono, di or tri carboxylic acids.

In a preferred embodiment, the acid comprises or consists of a hydroxy carboxylic acid, particularly but not limited to citric acid and tartaric acid. In another preferred embodiment the acetylenic compound, such as but not limited to acetylene dicarboxylic acid, also has acidic properties and therefore no further acid is required.

If present, the acid may be used in the etching composition in an amount of from about 0.1% to about 5% by weight, more preferably of from about 0.2% to about 4% by weight, even more preferably of from about 0.3% to about 3% by weight most preferably of from about 0.5 to about 2% by weight.

### Organic Solvents

Even not preferred, the etching composition may optionally comprise one or more organic solvents.

In individual cases, a composition according to the invention as defined herein may further comprise as an optional additional component: One or more water-miscible organic solvents, preferably selected from the group consisting of tetrahydrofuran (THF), N-methylpyrrolidone (NMP), di-methyl formamide (DMF), dimethyl sulfoxide (DMSO), ethanol, isopropanol, butyldiglycol, butylglycol, sulfolane (2,3,4,5-tetrahydrothiophene-1,1-dioxide) and mixtures thereof; more preferably selected from the group consisting of THF, NMP, DMF, DMSO, sulfolane and mixtures thereof.

The term “water-miscible organic solvent” in the context of the present invention preferably means that an organic solvent fulfilling this requirement is miscible with water at least in a 1:1 (w/w) ratio at 20° C. and ambient pressure. Preferably the or at least one water-miscible organic solvent (H) is sulfolane. Particularly, preferred are compositions according to the present invention which do not comprise one or more water-miscible organic solvents.

In individual cases, a composition according to the invention as defined herein (or a composition according to the invention as described above or below as being preferred) is preferred wherein the total amount of the one or more water-miscible organic solvents, (i.e. the solvent component) present in an amount of from about 0.1 to about 30% by weight, preferably of from about 0.5 to about 10% by weight, more preferably of from about 1 to about 7.5% by weight, even more preferably of from about 1 to about 6% by weight, based on the total weight of the composition.

Most preferably the etching composition is an aqueous solution that is essentially free of organic solvents. Essentially free herein means that the content of organic solvents is below 1% by weight, preferably below 0.1% by weight, even more preferably below 0.01% by weight, most preferably below the detection limit.

### Surfactants

The composition may also further comprise one or more surfactants.

Preferred surfactants are selected from the group consisting of
(i) anionic surfactants, preferably selected from the group consisting of ammonium lauryl sulfate, fluorosurfactants, preferably selected from the group consisting of perfluorinated alkylsulfonamide salts (preferably perfluorinated, N-substituted alkylsulfonamide ammonium salts, PNAAS), perfluorooctanesulfonate, perfluorobutanesulfonate, perfluorononanoate and perfluorooctanoate; alkyl-aryl ether phosphates and alkyl ether phosphates;
(ii) zwitterionic surfactants, preferably selected from the group consisting of (3-[(3-cholamidopropyl)dimethylammonio]-1-propanesulfonate) (“CHAPS”), cocamidopropyl hydroxysultaine (CAS RN 68139-30-0), {[3-(dodecanoylamino)propyl](dimethyl)-ammonio}acetate, phosphatidylserine, phosphatidylethanolamine, phosphatidylcholine; and
(iii) non-ionic surfactants, preferably selected from the group consisting of glucoside alkyl ethers, glycerol alkyl ethers, cocamide ethanolamines and lauryldimethylaminoxide.

More preferred surfactants in compositions according to the invention are or comprise perfluorinated, N-substituted alkylsulfonamide ammonium salts. Preferred surfactants (E) in compositions according to the invention do not comprise metals or metal ions.

Particular preferred surfactants are those of formula F1

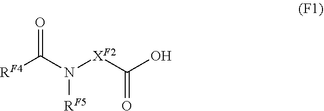

wherein
X^{F2} is a C₁, to C₄ alkanediyl;
R^{F4} is a C₁₂ to C₃₀ alkyl or a C₁₂ to C₃₀ alkenyl; and
R^{F5} is a C₁ to C₄ alkyl.

A composition according to the invention as defined herein is also preferred wherein the amount of the one or more surfactants of the surfactant present is of from about 0.0001 to about 1% by weight, preferably of from about 0.0005 to about 0.5% by weight, more preferably in an amount of from about 0.001 to about 0.01% by weight, based on the total weight of the composition.

### Chelating Agents

The etching composition may optionally comprise one or more chelating agents.

Preferred chelating agents are of 1,2-cyclohexylenedinitrilotetraacetic acid, 1,1,1,5,5,5-hexafluoro-2,4-pentane-dione, acetylacetonate, 2,2′-azanediyldiacetic acid, ethylenediamine-tetra-acetic acid, etidronic acid, methanesulfonic acid, acetylacetone, 1,1,1-trifluoro-2,4-pentanedione, 1,4-benzoquinone, 8-hydroxyquinoline, salicyli-dene aniline; tetrachloro-1,4-benzoquinone, 2-(2-hydroxyphenyl)-benzoxazol, 2-(2-hydroxyphenyl)-benzothiazole, hydroxyquinoline sulfonic acid, sulfosali-cylic acid, salicylic acid, pyridine, 2-ethylpyridine, 2-methoxypyridine, 3-methoxypyridine, 2-picoline, dimethylpyridine, piperidine, piperazine, tri-ethylamine, triethanolamine, ethylamine, methylamine, isobutylamine, tert-butylamine, tributylamine, dipropylamine, dimethylamine, diglycol amine, monoethanolamine, methyldiethanolamine, pyrrole, isoxazole, bipyridine, py-rimidine, pyrazine, pyridazine, quinoline, isoquinoline, indole, 1-methylimidazole, diisopropylamine, diisobutylamine, aniline, pentamethyldi-ethylenetriamine, acetoacetamide, ammonium carbamate, ammonium pyr-rolidinedithiocarbamate, dimethyl malonate, methyl acetoacetate, N-methyl acetoacetamide, tetramethylammonium thiobenzoate, 2,2,6,6-tetramethyl-3,5-heptanedione, tetramethylthiuram disulfide, lactic acid, ammonium lactate, formic acid, propionic acid, gamma-butyrolactone, and mixtures thereof;

In a preferred embodiment the chelating agent may be Diethylenetriaminepentaacetic acid (DTPA) or may comprise DTPA as well as one or more of the other chelating agents above. Compositions comprising DTPA as chelating agent have shown particularly low etch rates for silicon oxide.

A composition according to the invention as defined herein is also preferred wherein the amount of the one or more chelating agents present is of from about 0.005 to about 2% by weight, preferably of from about 0.01 to about 1% by weight, more preferably of from about 0.02 to about 0.2% by weight, based on the total weight of the composition.

### Composition

In a preferred embodiment the pH of the etching composition is from 4 to 8, particularly from 5 to 7. If the pH is too low, the silicon oxide etch rate is too high, if the pH is too high, the Si etch rate is too high. The pH of the bath may be adjusted by a pH adjustor, particularly ammonia.

A composition according to the invention as defined herein is specifically preferred wherein the composition consists of hydrogen peroxide, ammonium fluoride, a first selectivity enhancer of formula S2 or S4, optionally a second selectivity enhancer of formula S3, an additional selectivity enhancer of formula S31, optionally an acid, optionally a pH adjustor, and water, as defined herein and to be defined based on the examples.

A composition according to the invention as defined herein is specifically preferred wherein the composition consists of hydrogen peroxide, ammonium fluoride, a first selectivity enhancer of formula S3, optionally a surfactant of formula S4, an additional selectivity enhancer of formula S31, optionally an acid, optionally a pH adjustor, and water, as defined herein and to be defined based on the examples.

A composition is particularly preferred wherein the composition comprises or consists of
(a) one or more oxidizing agents, selected from a peroxide, and preferably the one or more oxidizing agent consist of or comprise hydrogen peroxide, in an amount of from about 1 to about 10% by weight, preferably from about 2 to 8% by weight, even more preferably from about 3 to about 7% by weight, most preferably of from about 4 to about 6% by weight;
(b) one or more etchants comprising a source of fluoride ions, selected from the group consisting of ammonium fluoride, ammonium bifluoride, triethanolammonium fluoride, diglycolammonium fluoride, methyldiethanolammonium fluoride, tetramethylammonium fluoride, triethylamine trihydrofluoride, hydrogen fluoride, fluoroboric acid, tetrafluoroboric acid, ammonium tetrafluoroborate, fluoroacetic acid, ammonium fluoroacetate, trifluoroacetic acid, fluorosilicic acid, ammonium fluorosilicate, tetrabutylammonium tetrafluoroborate and mixtures thereof, and preferably consists of or comprises ammonium fluoride, hydrogen fluoride or a combination thereof, in an amount of from about 1 to about 14% by weight, preferably of from about 2 to about 12% by weight, more preferably of from about 4 to about 10% by weight, even more preferably of from about 4 to about 10% by weight, most preferably of from about 6 to about 8% by weight;
(c) a first selectivity enhancer of formula S1, particularly of formula S2, S3, or S4 in an amount of from about 0.0005 to about 0.02% by weight, preferably of from about 0.005 to about 0.015% by weight;
(d) if the first selectivity enhancer is not a compound of formula S3, optionally a second selectivity enhancer of formula S3 in an amount of from about 0.1 to about 3% by weight, preferably of from about 0.5 to about 2% by weight;
(e) an additional selectivity enhancer of formula S31 in an amount of from 0.01 to 5% by weight, preferably of from 0.1 to 1% by weight;
(f) one or more acids selected from an inorganic acid and an organic acid, preferably an organic acid, more preferably a C₁ to C₁₀ mono, di or tri carboxylic acid, even more preferably a hydroxycarboxylic acid, even more preferably a dihydroxydicarboxylic acid, most preferably tartaric acid, or a combination thereof, and preferably consists of or comprises tartaric acid in an amount of from about 0.1% to about 5% by weight, more preferably of from about 0.2% to about 4% by weight, even more preferably of from 0.3% to 3% by weight most preferably of from 0.5 to 2% by weight;
(g) optionally one or more surfactants selected from the group consisting of (i) anionic surfactants, preferably selected from the group consisting of ammonium lauryl sulfate, fluorosurfactants, preferably selected from the group consisting of perfluorinated alkylsulfon-amide salts (preferably perfluorinated, N-substituted alkylsulfonamide ammonium salts), perfluorooctanesulfonate, perfluorobutanesulfonate, perfluorononanoate and perfluorooctanoate; alkyl-aryl ether phosphates and alkyl ether phosphates, (ii) zwitterionic surfactants, preferably selected from the group consisting of (3-[(3-cholamidopropyl)dimethyl-ammonio]-1-propanesulfonate), cocamidopropyl hydroxysultaine, {[3-(dodecanoylamino)propyl]-(dimethyl)ammonio}acetate, phosphatidylserine, phosphatidylethanolamine, phosphatidylcholine, (iii) non-ionic surfactants, preferably selected from the group consisting of glucoside alkyl ethers, glycerol alkyl ethers, cocamide ethanolamines and lauryldime-thylaminoxide; and preferably the one or more surfactants are or comprise a compound of formula F1, in an amount of from about 0.0005 to about 0.5% by weight, more preferably in an amount of from about 0.001 to about 0.01% by weight;
(h) optionally one or more chelating agents selected from the group consisting of diethylenetriaminepentaacetic acid, 1,2-cyclohexylenedinitrilotetraacetic acid, 1,1,1,5,5,5-hexafluoro-2,4-pentane-dione, acetylacetonate, 2,2′-azanediyldiacetic acid, ethylenediamine-tetra-acetic acid, etidronic acid, methanesulfonic acid, acetylacetone, 1,1,1-trifluoro-2,4-pentanedione, 1,4-benzoquinone, 8-hydroxyquinoline, salicyli-dene aniline; tetrachloro-1,4-benzoquinone, 2-(2-hydroxyphenyl)-benzoxazol, 2-(2-hydroxyphenyl)-benzothiazole, hydroxyquinoline sulfonic acid, sulfosalicylic acid, salicylic acid, pyridine, 2-ethylpyridine, 2-methoxypyridine, 3-methoxypyridine, 2-picoline, dimethylpyridine, piperidine, piperazine, tri-ethylamine, triethanolamine, ethylamine, methylamine, isobutylamine, tert-butylamine, tributylamine, dipropylamine, dimethylamine, diglycol amine, monoethanolamine, methyl-diethanolamine, pyrrole, isoxazole, bipyridine, py-rimidine, pyrazine, pyridazine, quinoline, isoquinoline, indole, 1-methylimidazole, diisopropylamine, diisobutylamine, aniline, penta-methyldiethylenetriamine, acetoacetamide, ammonium carbamate, ammonium pyrrolidine-dithiocarbamate, dimethyl malonate, methyl acetoacetate, N-methyl acetoacetamide, tetra-methylammonium thiobenzoate, 2,2,6,6-tetramethyl-3,5-heptanedione, tetramethylthiuram disulfide, lactic acid, ammonium lactate, formic acid, propionic acid, gamma-butyrolactone, and mixtures there-of, and preferably is or comprises 1,2-cyclohexylenedinitrilotetraacetic acid, in an amount of from about 0.005 to about 2 wt %, preferably in a total amount of from about 0.01 to about 1 wt %, more preferably in a total amount of from about 0.02 to about 0.2 wt %, based on the total weight of the composition;
(k) water as balance to a total of 100 wt.-% of the composition in each case;
and
(l) optionally one or more water-miscible organic solvents, preferably selected from the group consisting of tetrahydrofuran (THF), N-methylpyrrolidone (NMP), di-methyl formamide (DMF), dimethyl sulfoxide (DMSO) and sulfolane (2,3,4,5-tetrahydrothiophene-1,1-dioxide) and mixtures thereof, in an amount of from about 0.1 to about 30 wt %, preferably of from about 0.5 to about 10 wt %, more preferably of from about 1 to about 7.5 wt %, even more preferably of from about 1 to about 6 wt %;
all based on the total weight of the composition, wherein the pH of the composition is of from about 4 to about 8, preferably of from about 5 to about 7, and wherein the % amounts of the components add to 100% by weight in each case.

### Application

The composition is particularly useful for selectively etching a silicon germanium alloy (SiGe) layer in the presence of a Si layer, in particular crystalline Si and preferably in the presence of silicon oxide.

It will be appreciated that it is common practice to make concentrated forms of the compositions to be diluted prior to use. For example, the compositions may be manufactured in a more concentrated form and thereafter diluted with water, at least one oxidizing agent, or other components at the manufacturer, before use, and/or during use. Dilution ratios may be in a range from about 0.1 parts diluent to 1 parts composition concentrate to about 100 parts diluent to 1 part composition concentrate.

Accordingly, one embodiment relates to a kit including, in one or more containers, one or more components adapted to form the compositions described herein. Preferably, one container comprises the at least one oxidizing agent and a second container comprises the remaining components, e.g., at least one etchant, at least selectivity enhancer, water, and optionally other components described herein, for combining at the fab or the point of use.

In the use of the compositions described herein, the composition typically is contacted with the device structure for a sufficient time of from about 3 minutes to about 60 minutes, preferably about 5 minutes to about 20 minutes in a batch process and about 20 seconds to about 5 minutes, preferably about 30 seconds to about 3 minutes in a single wafer process. In the use of the compositions described herein, the composition typically is contacted with the device structure at temperature in a range of from about 10° C. to about 80° C., preferably about 20° C. to about 60° C. Such contacting times and temperatures are illustrative, and any other suitable time and temperature conditions may be employed that are efficacious to achieve the required removal selectivity. One advantage of the composition according to the present invention is its low temperature dependence of the SiGe/Si etch ratio. Particularly the SiGe etch rate and the SiGe/Si etch ratio is still very high at temperatures below 30° C. so that the substrates may be processed at room temperature.

Following the achievement of the desired etching action, the composition can be readily removed from the microelectronic device to which it has previously been applied, e.g., by rinse, wash, or other removal step(s), as may be desired and efficacious in a given end use application of the compositions of the present invention. For example, the device may be rinsed with a rinse solution including deionized water, an organic solvent, and/or dried (e.g., spin-dry, N₂, vapor-dry etc.).

It may be useful to clean the blanket wafer surfaces for approx 30 s with an aqueous solution containing 0.1% to 1% by weight HF at room temperature, then dipped into UPW for 2-3 s and dried with compressed air. However, by using the composition according to the present invention, it is possible and preferred to omit such pretreatment with HF.

The etching composition described herein may be advantageously used for selectively etching a SiGe layer in the presence of a Si layer and particularly in the presence of a silicon oxide layer.

The etching composition described herein may be advantageously used in a process of selectively removing a silicon germanium alloy layer from a surface of a microelectronic device relative to a Si layer and preferably a silicon oxide layer, the process comprising:
(a) providing a microelectronic device surface that includes the silicon germanium alloy layer and the Si layer and a layer comprising or consisting of silicon oxide,
(b) providing a composition as described above, and
(c) contacting the surface with the composition for a time and at a temperature effective to selectively remove the silicon-germanium alloy layer relative to the Si layer and the layer comprising or consisting of silicon oxide.

Preferably the SiGe etch rates of the compositions according to the invention are 200 A/min or more, more preferably 300 A/min or more. Preferably the Si etch rates of the compositions according to the invention are 2 A/min or below, more preferably 1 A/min or below. Preferably the etch rates of SiOₓ, SiN and SiON with the compositions according to the invention are 2 A/min or below, more preferably 1 A/min or below. Preferably the etch rate of the silicon-germanium layer is at least 500, preferably 750, even more preferably 1000, even more preferably 2000, most preferably more than 5000 times faster than the etch rate of the Si layer (SiGe/Si selectivity).

The etching composition described herein may be advantageously used in a process for the manufacture of a semiconductor device, comprising the step of selectively removing silicon-germanium from a surface of a microelectronic device relative to a Si material and a silicon oxide material.

All percent, ppm or comparable amounts refer to the weight with respect to the total weight of the respective composition except where otherwise indicated. All cited documents are incorporated herein by reference.

The following examples shall further illustrate the present invention without restricting the scope of this invention.

### EXAMPLES

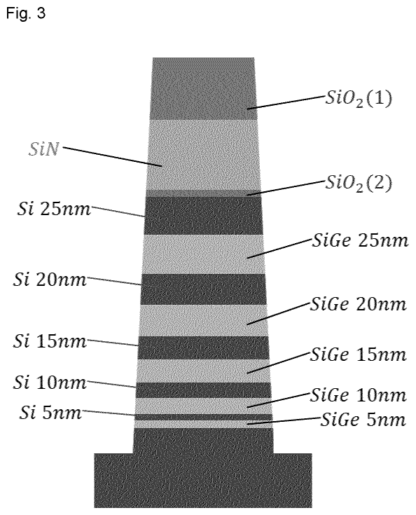

The following substrates were used: SALSA Ill by IMEC as schematically shown in FIG. 3. The substrate comprised several stacked SiGe and Si layers. SALSA 3 layer build up from top to bottom: SiO₂ (50 nm)-SiN (50 nm)-SiO₂ (5 nm)-Si (25 nm)-SiGe (25 nm)-Si (20 nm)-SiGe (20 nm)-Si (15 nm)-SiGe (15 nm)-Si (10 nm)-SiGe (10 nm)-Si (5 nm)-SiGe (5 nm)-Si<100> Wafer (ca. 0.70 mm). All SiGe layer contained 25% by weight of Germanium. The Si layers consisted of crystalline Si.

The following materials were used in electronic grade purity:
H₂O₂ (31%)
NH₄F
DL-tartaric acid
citric acid
Surfynol® 104 (available from Evonik)

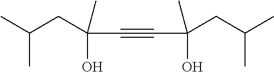 [SMILES: CC(C)CC(C)(O)C#CC(C)(O)CC(C)C]

(3-Acrylamidopropyl)-trimethylammonium chloride
Diethylenetriaminepentaacetic acid (DTPA)
Ethylenediaminetetracetic acid (EDTA)
Hexamethylenetetramine

All amounts given for the compounds in the compositions are absolute amounts, i.e. excluding water, in the overall mixture.

### Etch Bath Preparation:

The etching bath vessel was set to a temperature of 24° C.+/−0.5° C. The mixing of the different components was done in the following order: Water, NH₄F, Surfynol 104, (3-Acrylamidopropyl)-trimethylammonium chloride, DTPA or EDTA, an acid, NH₄OH and H₂O₂.

### Etching:

After mixing all components, the coupons containing the microstructures were insert into the bath for 60 seconds. After etching, the coupons were rinsed with UPW and dried with compressed air.

### Example 1

The compositions listed in table 1a were prepared.

TABLE 1a

| | Ex 1.1 | Ex 1.2 |
|---|---|---|
| NH₄F | 14.0% | 7.0% |
| H₂O₂ | 10.0% | 5.0% |
| Surfynol ® 104 | 0.005% | 0.010% |
| citric acid | 1.00% | |
| DL-tartaric acid | | 0.5% |
| DTPA | | 0.05% |
| (3-Acrylamidopropyl)-trimethylammonium chloride | | 0.3% |
| Water | 75.0% | 75.0% |

The pH was adjusted to 6.1 by adding NH₄OH (if necessary).

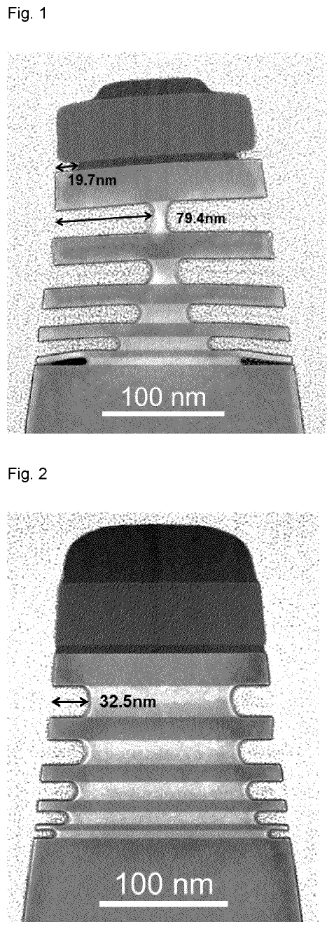

The etching rates in A/min were determined by TEM according to the lateral etching depth of the top SiGe25 and Si layers. The results are depicted in table 1b and the substrate etched with the compositions according to examples 1.1 and 1.2 is shown in FIGS. 1 and 2, respectively.

TABLE 1b

| | Ex 1.1 | Ex 1.2 |
|---|---|---|
| Si | 0 Å/min | 0 Å/min |
| SiGe(25%) | 794 Å/min | 325 Å/min |
| SiO₂ | 197 Å/min | 0 Å/min |

Table 1b and FIG. 1 show that Experiment 1.2 has no lateral loss of SiO₂. Even if the SiGe etch rate is much lower the overall selectivity of SiGe vs Si or SiO₂ is significantly increased.

### Example 2

Example 1 was repeated with the compositions listed in table 2a and the results are depicted in table 2b. The etching rates were determined by Ellipsometry by comparing the layer thickness before and after etching.

TABLE 2a

| | Ex 2.1 | Ex 2.2 | Ex 2.3 |
|---|---|---|---|
| NH₄F | 7.0% | 7.0% | 7.0% |
| H₂O₂ | 5.0% | 5.0% | 5.0% |
| Surfynol ® 104 | 0.01% | 0.01% | 0.01% |
| DL-tartaric acid | 0.5% | 0.5% | 0.5% |
| DTPA | 0.05% | | 0.05% |
| EDTA | | 0.05% | |
| (3-Acrylamidopropyl)- | 0.3% | 0.3% | |
| trimethylammonium chloride | | | |
| Hexamethylenetetramine | | | 0.3% |
| Water | 75.0% | 75.0% | 75.0% |

TABLE 2b

| | Ex 2.1 | Ex 2.2 | Ex 2.3 |
|---|---|---|---|
| Si | 0 Å/min | 0 Å/min | 1 Å/min |
| SiGe(25%) | 174 Å/min | 227 Å/min | 174 Å/min |
| SiO₂ | 0 Å/min | 20 Å/min | 111 Å/min |

Table 2b shows that (3-acrylamidopropyl)-trimethylammonium chloride used in experiments 2.1 and 2.2 has a strong suppressing effect on the lateral loss of SiO₂ in comparison to Hexamethylenetetramine in example 2.3. DTPA further lowers the SiO₂ etch rate compared to EDTA.

### Example 3

Several bath stabilizers were tested.

The compositions listed in table 3a were prepared. The etching rates were determined by Ellipsometry by comparing the layer thickness before and after etching. The etch rates were determined after 0, 1, 2, 5, and 12 days as described in Example 1. The SiGe25 etch rates are shown in table 3b. No significant influence on the Si and SiO₂ etch rates could be observed.

TABLE 3a

| | Ex 3.1 | Ex 3.2 | Ex 3.3 | Ex 3.4 |
|---|---|---|---|---|
| NH₄F | 7.0% | 7.0% | 7.0% | 7.0% |
| H₂O₂ | 5.0% | 5.0% | 5.0% | 5.0% |
| Surfynol ® 104 | 0.01% | 0.01% | 0.01% | 0.01% |
| DL-tartaric acid | 0.5% | | | |
| Citric Acid | | 0.5% | | |
| Acetic Acid | | | 0.5% | |
| Phosphoric Acid | | | | 0.5% |
| DTPA | 0.05% | 0.05% | 0.05% | 0.05% |
| (3-Acrylamidopropyl)- | 0.3% | 0.3% | 0.3% | 0.3% |
| trimethylammonium chloride | | | | |
| Water | 75.0% | 75.0% | 75.0% | 75.0% |

TABLE 3b
aging time

| | 0 d | 1 d | 2 d | 5 d | 12 d |
|---|---|---|---|---|---|
| Ex 3.1 | 193 Å/min | 199 Å/min | 199 Å/min | 192 Å/min | 201 Å/min |
| Ex 3.2 | 169 Å/min | 147 Å/min | 152 Å/min | 120 Å/min | 115 Å/min |
| Ex 3.3 | 205 Å/min | 200 Å/min | 204 Å/min | 198 Å/min | 159 Å/min |
| Ex 3.4 | 226 Å/min | 216 Å/min | 222 Å/min | 200 Å/min | 156 Å/min |

Table 3b shows that the etching composition comprising tartaric acid (example 3.1) shows no significant reduction of the SiGe25 etch rate over the time. In contrast, the SiGe25 etch rate of compositions comprising citric acid, acetic acid, and phosphoric acid is significantly reduced.

1. A composition for selectively etching a silicon germanium alloy (SiGe) layer in the presence of a silicon layer, the composition comprising:
(a) 1 to 10% by weight of an oxidizing agent;
(b) 1 to 14% by weight of an etchant comprising a source of fluoride ions;
(c) 0.001 to 3% by weight of a selectivity enhancer of formula Si 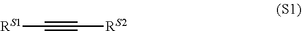
(d) 0.001 to 3% by weight of an additional selectivity enhancer of formula S31 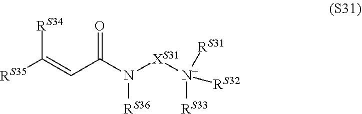
and
(e) water;
wherein
R^{S1} is selected from the group consisting of X^{S}—OH and Y^{S}—(CO)—OH;
R^{S2} is selected from the group consisting of (i) R^{S1}, (ii) H, (iii) C₁ to C₁₀ alkyl, (iv) C₁ to C₁₀ alkenyl, (v) C₁ to C₁₀ alkynyl, and (vi) —X^{S1}—(O—C₂H₃R^{S6})ₘ—OR^{S6};
R^{S6} is selected from the group consisting of H and C₁ to C₆ alkyl;
R^{S31}, R^{S32}, R^{S33} are independently selected from the group consisting of C₁ to C₆ alkyl;
R^{S34}, R^{S35}, R^{S36} are independently selected from the group consisting of H and C₁ to C₆ alkyl;
X^{S} is selected from the group consisting of a linear or branched C₁ to C₁₀ alkanediyl, a linear or branched C₂ to C₁₀ alkenediyl, a linear or branched C₂ to C₁₀ alkynediyl, and —X^{S1}—(O—C₂H₃R^{S6})ₘ;
Y^{S} is selected from the group consisting of a chemical bond and X^{S};
X^{S1} is a C₁ to C₆ alkanediyl;
X^{S31} is selected from the group consisting of a C₁ to C₆ alkanediyl and —X^{S1}—(O—C₂H₃R^{S6})ₘ—; and
m is an integer in a range of from 1 to 10.

2. The composition according to claim 1, wherein the oxidizing agent is a peroxide.

3. The composition according to claim 1, wherein the etchant is selected from the group consisting of hydrogen fluoride, ammonium fluoride, ammonium bifluoride, triethanolammonium fluoride, diglycolammonium fluoride, methyldiethanolammonium fluoride, tetramethylammonium fluoride, triethylamine tri-hydrofluoride, fluoroboric acid, tetrafluoroboric acid, ammonium tetrafluoroborate, fluoroacetic acid, ammonium fluoroacetate, trifluoroacetic acid, fluorosilicic acid, ammonium fluorosilicate, tetrabutylammonium tetrafluoroborate and mixtures thereof.

4. The composition according to claim 1, wherein the selectivity enhancer is present in an amount of
(a) from 0.0005 to 0.02% by weight if R^{S1} is X^{S}—OH, or
(b) from 0.1 to 3% by weight if R^{S1} is Y^{S}—(CO)—OH.

5. The composition according to claim 1, wherein R^{S1} is X^{S}—OH and X^{S} is a C₁ to C₈ alkanediyl.

6. The composition according to claim 5, wherein the selectivity enhancer is a compound of formula S2 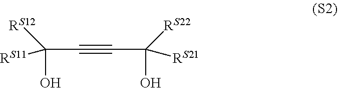
wherein
R^{S11}, R^{S21} are independently selected from the group consisting of a C₁ to C₆ alkyl, and
R^{S12}, R^{S22} are independently selected from the group consisting of H and a C₁ to C₁₀ alkyl.

7. The composition according to claim 1, wherein the first selectivity enhancer is a compound of formula S3 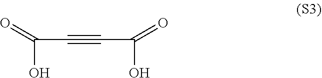
or, if the first selectivity enhancer is a compound of formula S2, the composition further comprises a second acetylenic compound of formula S3.

8. The composition according to claim 1, wherein
R^{S31}, R^{S32}, R^{S33} are independently selected from the group consisting of methyl, ethyl, propyl and butyl;
R^{S34}, R^{S35}, R^{S36} are independently H or selected from the group consisting of methyl, ethyl, propyl and butyl;
X^{S31} is selected from the group consisting of methanediyl, ethanediyl, propanediyl, butanediyl, and —X^{S1}—(O—C₂H₃R^{S6})ₘ—;
R^{S6} is H or selected from the group consisting of methyl and ethyl;
X^{S1} is selected from the group consisting of methanediyl, ethanediyl, propanediyl, and butanediyl; and
m is an integer in a range of from 1 to 6.

9. The composition according to claim 1, wherein
R^{S31}, R^{S32}, R^{S33} are independently selected from the group consisting of methyl and ethyl;
R^{S34}, R^{S35}, R^{S36} are independently selected from the group consisting of H or methyl;
X^{S31} is selected from the group consisting of methanediyl, ethane-1,2-diyl, propane-1,3-diyl, and butane-1,4-diyl;
X^{S1} is selected from the group consisting of methanediyl, ethane-1,2-diyl, propane-1,3-diyl, and butane-1,4-diyl; and
m is an integer in a range of from 1 to 6.

10. The composition according to claim 1, wherein the second selectivity enhancer is a compound of formula S32 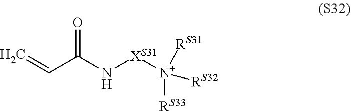
wherein
R^{S31}, R^{S32}, R^{S33} are independently selected from the group consisting of methyl, ethyl, propyl and butyl;
X^{S31} is selected from the group consisting of methanediyl, ethanediyl, propanediyl, and butanediyl.

11. The composition according to claim 1, wherein the additional selectivity enhancer is present in an amount of from 0.005 to 2% by weight.

12. The composition according to claim 1, further comprising an organic acid selected from the group consisting of a hydroxy carboxylic acids.

13. A method of using a composition according to claim 1, the method comprising using the composition for selectively etching a SiGe layer in the presence of a silicon layer and optionally a silicon oxide layer.

14. A process of selectively removing a silicon germanium layer from a surface of a microelectronic device relative to a silicon layer and optionally a silicon oxide layer, the process comprising:
(a) providing a microelectronic device surface that includes the silicon germanium layer and the silicon layer and the optional silicon oxide layer,
(b) providing the composition according to claim 1, and
(c) contacting the surface with the composition for a time and at a temperature effective to selectively remove the silicon-germanium layer relative to the Si layer and the optional silicon oxide layer.

15. A process for the manufacture of a semiconductor device, comprising the step of selectively removing a silicon-germanium layer from a surface of a microelectronic device relative to a silicon layer and optionally to a silicon oxide layer according to claim 14.

16. The composition according to claim 1, wherein the oxidizing agent is hydrogen peroxide.

17. The composition according to claim 1, wherein the etchant is hydrogen fluoride.

18. The composition according to claim 1, wherein R^{S1} is X^{S}—OH and X^{S} is a C₁ to C₆ alkane-1,1-diyl.

19. The composition according to claim 5, wherein the selectivity enhancer is is a compound of formula S2 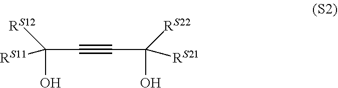
wherein
each R^{S11}, R^{S21} is independently selected from the group consisting of ethyl, propyl, butyl, pentyl and hexyl and
each R^{S12}, R^{S22} is independently selected from the group consisting of H, methyl and ethyl.

20. The composition according to claim 7, wherein the first selectivity enhancer is a compound of formula S2, wherein the composition further comprises a second acetylenic compound of formula S3.
